(19) United States
(12) Patent Application Publication
(10) Pub. No.: US 2015/0381112 A1
(43) Pub. Date: Dec. 31, 2015

(54) FILTER WITH AN AUXILIARY MIXING PATH

(71) Applicant: QUALCOMM Incorporated, San Diego, CA (US)

(72) Inventors: Chuan Wang, San Diego, CA (US); Wu-Hsin Chen, San Diego, CA (US); Aleksandar Miodrag Tasic, San Diego, CA (US); Jusung Kim, San Diego, CA (US)

(21) Appl. No.: 14/317,894

(22) Filed: Jun. 27, 2014

(51) Int. Cl. H03D 7/14; H04B 1/40

(52) U.S. Cl. CPC H03D 7/1466; H04B 1/40

(57) ABSTRACT

An apparatus includes an auxiliary mixing path configured to receive a differential signal. The apparatus also includes a filter having an input coupled to the auxiliary mixing path.

### I. FIELD

The present disclosure is generally related to a filter with an auxiliary mixing path.

### II. DESCRIPTION OF RELATED ART

Advances in technology have resulted in smaller and more powerful computing devices. For example, there currently exist a variety of portable personal computing devices, including wireless computing devices, such as portable wireless telephones, personal digital assistants (PDAs), and paging devices that are small, lightweight, and easily carried by users. More specifically, portable wireless telephones, such as cellular telephones and Internet protocol (IP) telephones, can communicate voice and data packets over wireless networks. Further, many such wireless telephones include other types of devices that are incorporated therein. For example, a wireless telephone can also include a digital still camera, a digital video camera, a digital recorder, and an audio file player. Also, such wireless telephones can process executable instructions, including software applications, such as a web browser application, that can be used to access the Internet. As such, these wireless telephones can include significant computing capabilities.

Wireless devices may include a transceiver to transmit signals and to receive signals. For example, the transceiver may include a transmission path (e.g., transmission circuitry) to transmit signals via a duplexer, and the transceiver may include a reception path (e.g., receive circuitry) to receive signals via the duplexer. In the transmission path, a transmission signal may be routed through the duplexer and transmitted via an antenna. In the reception path, an incoming signal may be received via the antenna and coupled through the duplexer to a low noise amplifier. A portion of the transmission signal may leak from the duplexer to the reception path. Transmission signal leakage may cause interference with the incoming signal processed by the reception path. The interference may cause second-order distortion, cross-modulation distortion, reduced linearity, etc. Thus, the interference may cause reduced signal quality of the incoming signal received via the antenna.

### III. BRIEF DESCRIPTION OF THE DRAWINGS

FIG. 1 shows a wireless device communicating with a wireless system;

FIG. 2 shows a block diagram of the wireless device in FIG. 1;

FIG. 3 is a diagram that depicts an exemplary embodiment of a jammer reduction system that may be deployed in the wireless device of FIG. 2;

FIG. 4 is a diagram that depicts an exemplary embodiment of a notch filter of the jammer reduction system of FIG. 3;

FIG. 5 is a diagram that depicts another exemplary embodiment of a jammer reduction system that may be deployed in the wireless device of FIG. 2;

FIG. 6 is a diagram that depicts another exemplary embodiment of a notch filter that is usable with the jammer reduction system of FIGS. 3 and 5; and

FIG. 7 is a flowchart that illustrates an exemplary embodiment of a method for reducing jammers that may be used by the wireless device of FIG. 2.

### IV. DETAILED DESCRIPTION

The detailed description set forth below is intended as a description of exemplary designs of the present disclosure and is not intended to represent the only designs in which the present disclosure can be practiced. The term “exemplary” is used herein to mean “serving as an example, instance, or illustration.” Any design described herein as “exemplary” is not necessarily to be construed as preferred or advantageous over other designs. The detailed description includes specific details for the purpose of providing a thorough understanding of the exemplary designs of the present disclosure. It will be apparent to those skilled in the art that the exemplary designs described herein may be practiced without these specific details. In some instances, well-known structures and devices are shown in block diagram form in order to avoid obscuring the novelty of the exemplary designs presented herein.

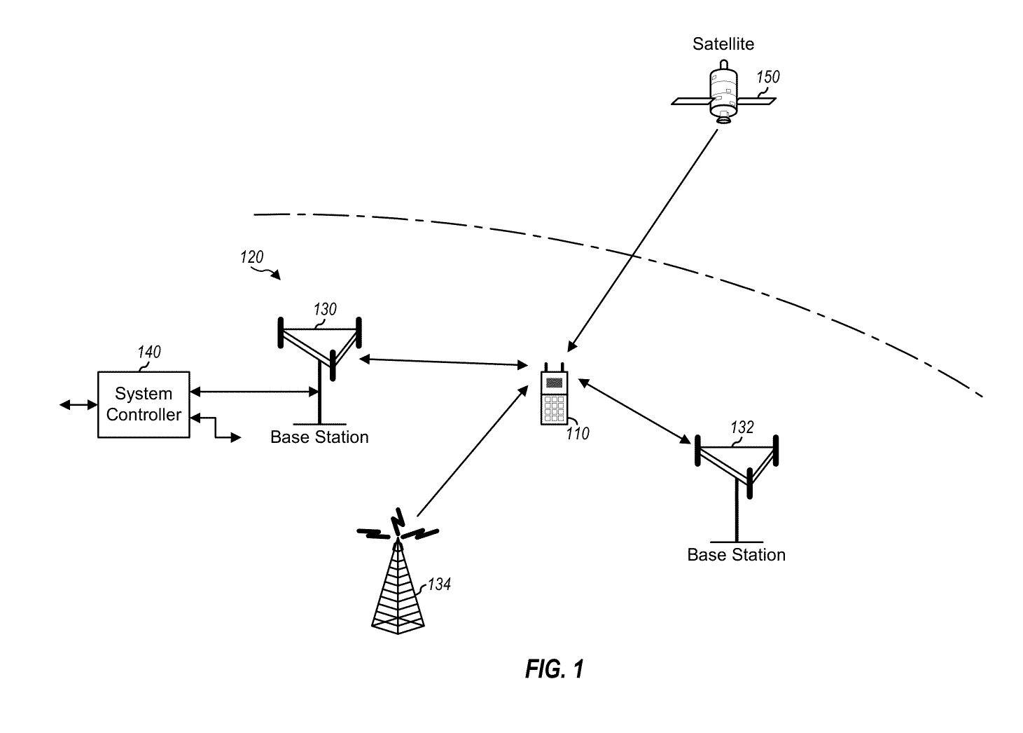

FIG. 1 shows a wireless device 110 communicating with a wireless communication system 120. Wireless communication system 120 may be a Long Term Evolution (LTE) system, a Code Division Multiple Access (CDMA) system, a Global System for Mobile Communications (GSM) system, a wireless local area network (WLAN) system, or some other wireless system. A CDMA system may implement Wideband CDMA (WCDMA), CDMA 1×, Evolution-Data Optimized (EVDO), Time Division Synchronous CDMA (TD-SCDMA), or some other version of CDMA. For simplicity, FIG. 1 shows wireless communication system 120 including two base stations 130 and 132 and one system controller 140. In general, a wireless system may include any number of base stations and any set of network entities.

Wireless device 110 may also be referred to as a user equipment (UE), a mobile station, a terminal, an access terminal, a subscriber unit, a station, etc. Wireless device 110 may be a cellular phone, a smartphone, a tablet, a wireless modem, a personal digital assistant (PDA), a handheld device, a laptop computer, a smartbook, a netbook, a cordless phone, a wireless local loop (WLL) station, a Bluetooth device, etc. Wireless device 110 may communicate with wireless system 120. Wireless device 110 may also receive signals from broadcast stations (e.g., a broadcast station 134), signals from satellites (e.g., a satellite 150) in one or more global navigation satellite systems (GNSS), etc. Wireless device 110 may support one or more radio technologies for wireless communication such as LTE, WCDMA, CDMA 1×, EVDO, TD-SCDMA, GSM, 802.11, etc.

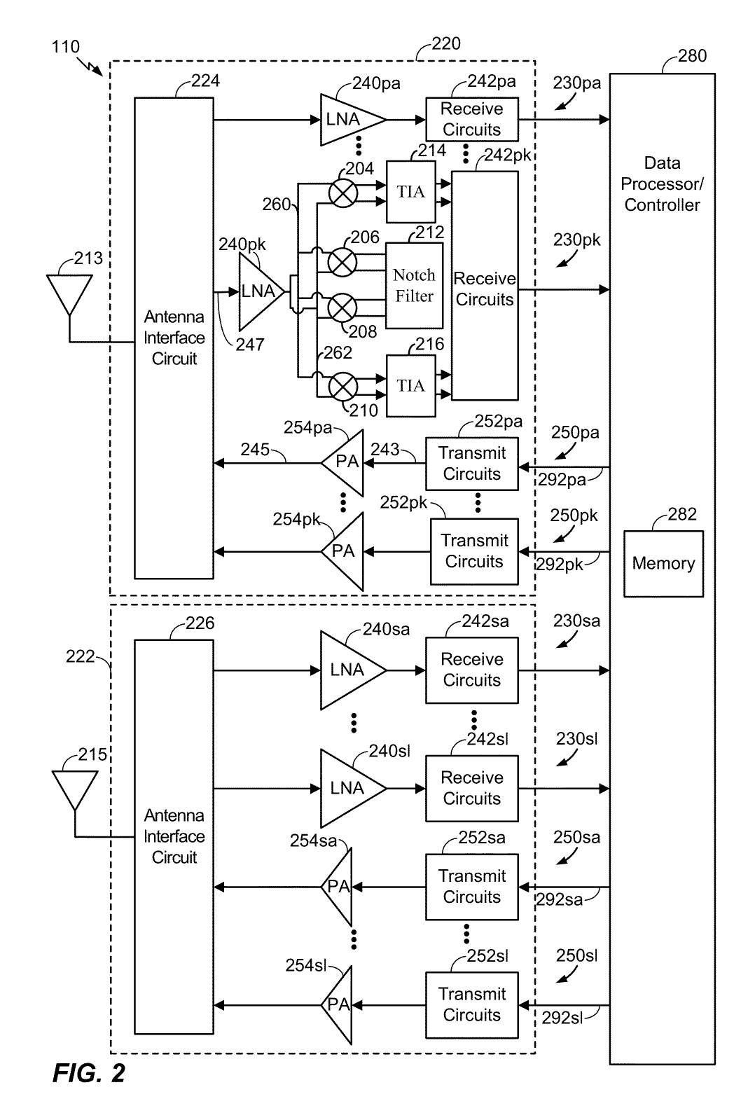

FIG. 2 shows a block diagram of an exemplary design of the wireless device 110 in FIG. 1. In this exemplary design, the wireless device 110 includes a transceiver 220 coupled to a primary antenna 213, a transceiver 222 coupled to a secondary antenna 215, and a data processor/controller 280. Transceiver 220 includes multiple (K) receivers 230pa to 230pk and multiple (K) transmitters 250pa to 250pk to support multiple frequency bands, multiple radio technologies, carrier aggregation, receive diversity, multiple-input multiple-output (MIMO) transmission from multiple transmit antennas to multiple receive antennas, etc. Transceiver 222 includes multiple (L) receivers 230sa to 230sl and multiple (L) transmitters 250sa to 250sl to support multiple frequency bands, multiple radio technologies, carrier aggregation, receive diversity, multiple-input multiple-output (MIMO) transmission from multiple transmit antennas to multiple receive antennas, etc.

In the exemplary design shown in FIG. 2, each transmitter 250pa-250pk and 250sa-250sl includes a transmit circuit 252pa-252pk and 252sa-252sl and a power amplifier (PA) 254pa-254pk and 254sa-254sl, respectively. For data transmission, data processor 280 processes (e.g., encodes and modulates) data to be transmitted and provides an analog output signal to a selected transmitter. For example, the transmitter 250pa may be the selected transmitter. Within transmitter 250pa, transmit circuits 252pa amplify, filter, and upconvert the analog output signal from baseband to radio frequency (RF) and provide a modulated RF signal 243. Transmit circuits 252pa may include amplifiers, filters, mixers, matching circuits, an oscillator, a local oscillator (LO) generator, a phase-locked loop (PLL), etc. A power amplifier 254pa receives and amplifies the modulated RF signal 243 and provides a transmit RF signal 245 having an output power level that is satisfactory for wireless transmission. The transmit RF signal 254 is routed through antenna interface circuit 224 and transmitted via antenna 213. Each remaining transmitter 250pk and 250sa-250sl in transceivers 220 and 222 may operate in a similar manner as transmitter 250pa.

In the exemplary design shown in FIG. 2, each receiver 230pa-230pk and 230sa-230sl includes an LNA 240pa-240pk and 240sa-240sl and a receive circuit 242pa-242pk and 242sa-242sl, respectively. For data reception, antenna 213 receives signals from base stations and/or other transmitter stations and provides a received RF signal, which is routed through an antenna interface circuit 224 and presented as an input RF signal to a selected receiver. Antenna interface circuit 224 may include switches, duplexers, transmit filters, receive filters, matching circuits, etc. The description below assumes that receiver 230pk is the selected receiver. Within receiver 230pk, an LNA 240pk amplifies the input RF signal and provides an output RF signal.

In certain circumstances, portions of the transmit RF signal from the power amplifier 254pa may be leaked to the LNA 240pk via the duplexer in the antenna interface circuit 224. Thus, the signal provided to the LNA 240pk may have signal components (e.g., components corresponding to the input RF signal from the antenna 213 or a “desired” reception signal) and jammer components (e.g., components corresponding to the transmit RF signal from the power amplifier 254pa). Although jammer components are described as due to a leaked transmit RF signal from the power amplifier 254pa, in other embodiments, jammer components may correspond to incoming signals at harmonics (e.g., frequencies) that are different from the “desired” reception signal. As a non-limiting example, the jammer components may correspond to, or include, Institute of Electrical and Electronics Engineers (IEEE) 802.11 (e.g., “Wife”) signals received via the antenna 213 at a different frequency than the “desired” reception signal.

The LNA 240pk may be configured to amplify the received signal 247 to generate an amplified signal. In one exemplary embodiment, the LNA 240pk may be a differential LNA configured to generate a first differential input signal 260 and a second differential input signal 262. The differential input signals 260, 262 may have signal components and jammer components. In a second exemplary embodiment, the LNA 240pk may be a single-ended LNA coupled to a transformer (not shown). The transformer in the second exemplary embodiment may generate the first differential input signal 260 and the second differential input signal 262.

The first differential input signal 260 and the second differential input signal 262 may be provided to a first main mixer 204, a first auxiliary mixer 206, a second auxiliary mixer 208, and a second main mixer 210. The auxiliary mixers 206, 208 may be included in an auxiliary mixing path, and the main mixers 204, 210 may be included in a main mixing path. In an exemplary embodiment, the first main mixer 204 and the first auxiliary mixer 206 are in-phase mixers, and the second auxiliary mixer 208 and the second main mixer 210 are quadrature mixers.

The first auxiliary mixer 206 may mix the first and second differential input signals 260, 262 with a local oscillator (LO) signal (not shown) to generate first and second in-phase auxiliary signals, respectively. The second auxiliary mixer 208 may mix the first and second differential input signals 260, 262 with the LO signal to generate first and second quadrature auxiliary signals, respectively. The auxiliary signals may include signal components and jammer components and may be provided to a notch filter 212.

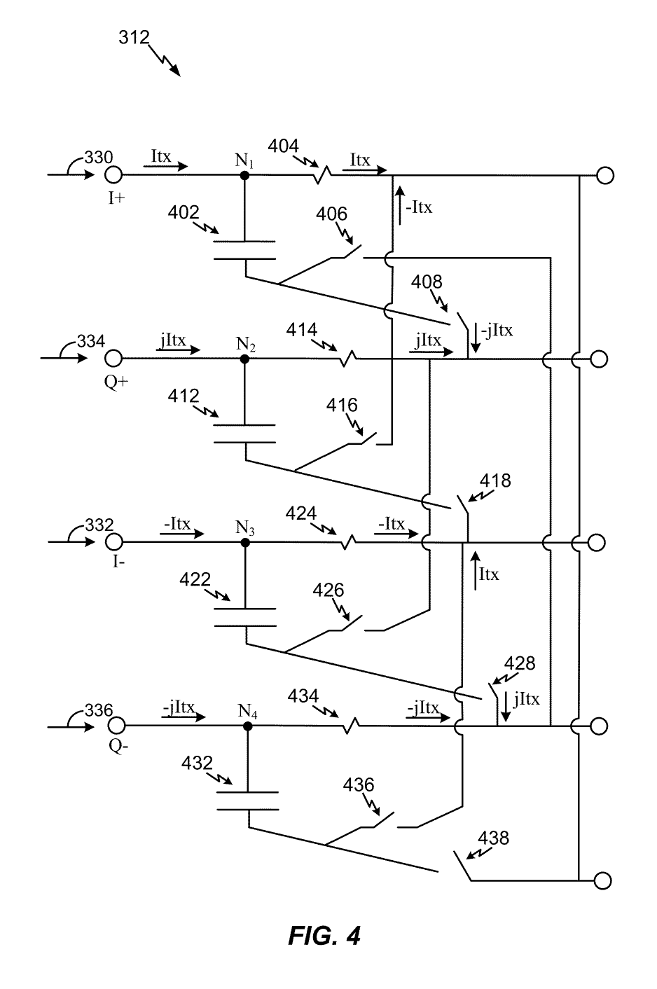

The notch filter 212 may operate as a poly-phase shifter to cancel (e.g., reduce or alleviate) jammer components (e.g., substantially reduce the transmit RF signal from the power amplifier 254pa). For example, the notch filter 212 may include a plurality of resistors and capacitors, as illustrated in FIG. 4. The notch filter 212 may be tuned to a frequency of the jammer components and may generate a phase-shift such that the in-phase and quadrature jammer components cancel each other out. The auxiliary mixers 206, 208 may be passive mixers such that cancellation at the notch filter 212 may generate a “low impedance state” at the inputs of the auxiliary mixers 206, 208 at the jammer frequency.

The main mixers 204, 210 may receive the “desired” reception signal (e.g., the signal components) from the differential input signals 260, 262 because jammer components are “canceled” out, or destructively interfered with, at the auxiliary paths via the up-converted phase-shifted jammer components. The first main mixer 204 may mix the desired reception signal with local oscillator signals to generate in-phase signals having signal components, and the second main mixer 210 may mix the desired reception signal with local oscillator signal to generate quadrature signals having signal components. The in-phase signals may be provided to a first transimpedance amplifier (TIA) 214 and to the receive circuits 242pk for further processing. The quadrature signals may be provided to a second TIA 216 and to the receive circuits 242pk for further processing.

Receive circuits 242pk down-convert the in-phase signals and the quadrature signals to baseband, amplify and filter the downconverted signal, filter the close-in frequency jammer, and provide an analog input signal to data processor 280. Receive circuits 242pk may include mixers, filters, amplifiers, matching circuits, an oscillator, a local oscillator (LO) generator, a phase locked loop (PLL), etc. Each remaining receiver 230pa and 230sa-230sl in transceivers 220 and 222 may operate in a similar manner as the receiver 230pk.

A receiver and a transmitter may also include other circuits not shown in FIG. 2, such as filters, matching circuits, etc. All or a portion of the transceivers 220 and 222 may be implemented on one or more analog integrated circuits (ICs), RF ICs (RFICs), mixed-signal ICs, etc. For example, LNAs 240pa-240pk and 240sa-240sk and receive circuits 242pa-242pk and 242sa-242sk may be implemented in one manner, which may be an RFIC, etc. The circuits in transceivers 220 and 222 may also be implemented in other manners.

Data processor/controller 280 may perform various functions for wireless device 110. For example, data processor 280 may perform processing for data being received via the receivers 230pa-230pk and 230sa-230sl and data being transmitted via transmitters 250pa-250pk and 250sa-250sl. Data processor/controller 280 may control the operation of the various circuits within transceivers 220 and 222. A memory 282 may store program code and data for the data processor/controller 280. Data processor/controller 280 may be implemented in one or more application specific integrated circuits (ASICs) and/or other ICs.

Wireless device 110 may support multiple frequency band groups, multiple radio technologies, and/or multiple antennas. Wireless device 110 may include a number of LNAs to support reception via the multiple frequency band groups, multiple radio technologies, and/or multiple antennas.

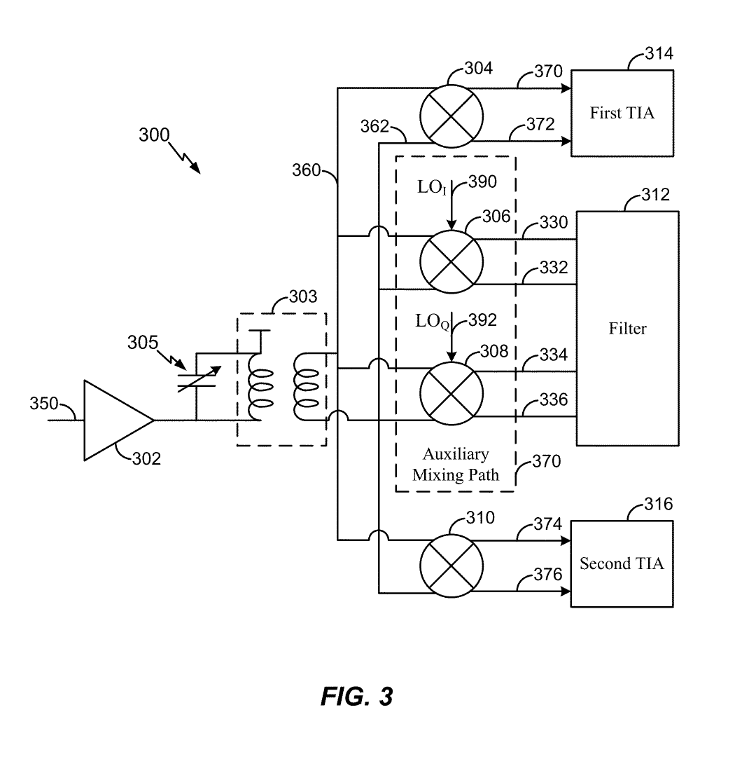

Referring to FIG. 3, an exemplary embodiment of a system 300 that is operable to reduce jammers is shown. As used herein, a “jammer” corresponds to any signal that has been leaked into receive circuitry of a transceiver. For example, a jammer may include a transmission signal (e.g., the transmit RF signal from the power amplifier 254 of FIG. 2), incoming signals at harmonics (e.g., frequencies) different from a “desired” reception signal (e.g., a Wifi signal), etc.

The system 300 includes a low noise amplifier (LNA) 302, a transformer 303, a first main mixer 304, a first auxiliary mixer 306, a second auxiliary mixer 308, a second main mixer 310, a filter 312 (e.g., a notch filter), a first transimpedance amplifier (TIA) 314, and a second TIA 316. In an exemplary embodiment, the LNA 302 may correspond to the LNA 240pk of FIG. 2, the mixers 304-310 may correspond to the mixers 204-210 of FIG. 2, the filter 312 may correspond to the notch filter 212 of FIG. 2, and the TIAs 314, 316 may correspond to the TIAs 214, 216 of FIG. 2.

An input signal 350 may be received at the LNA 302. The input signal 350 may include signal components and jammer components. The LNA 302 may be configured to amplify the input signal 350 and provide the resulting signal to the transformer 303. The transformer 303 may include a primary coil magnetically coupled to a secondary coil. In an exemplary embodiment, a tunable capacitor bank 305 may be coupled to a first terminal of the primary coil and to a second terminal of the primary coil. The tunable capacitor bank 305 may be configured to tune the resulting signal from the LNA 302 to a frequency of interest (e.g., tune to a particular center frequency of the “desired” reception signal). For example, the tunable capacitor bank 305 may filter outlier frequency components (e.g., jammer components). The tunable capacitor bank 305 may include multiple capacitors that are selectively activated via switches to tune to the frequency of interest. For example, switches may be selectively activated by the data processor/controller 280 of FIG. 2.

The transformer 303 may amplify the resulting filtered signal of LNA 302 (e.g., the filtered signal received from the tunable capacitor bank 305) to generate a first differential input signal 360 and a second differential input signal 362. For example, the transformer 303 may convert a single-ended signal into a differential signal. The differential input signals 360, 362 may include signal components and jammer components. In an exemplary embodiment, the first differential input signal 360 may correspond to the first differential input signal 260 of FIG. 2, and the second differential input signal 362 may correspond to the second differential input signal 262 of FIG. 2. The differential input signals 360, 362 may be provided to the first main mixer 304, the first auxiliary mixer 306, the second auxiliary mixer 308, and the second main mixer 310.

The first auxiliary mixer 306 and the second auxiliary mixer 308 may be included in an auxiliary mixing path 370. The first auxiliary mixer 306 may be an in-phase mixer, and the second auxiliary mixer 308 may be a quadrature mixer. The first auxiliary mixer 306 may be configured to mix (e.g., perform a down-conversion operation) the first differential input signal 360 with a local oscillator signal 390 (e.g., an in-phase local oscillator signal (LO_{I}) to generate a first in-phase auxiliary signal 330. The first auxiliary mixer 306 may also be configured to mix (e.g., perform a down-conversion operation) the second differential input signal 362 with the local oscillator signal 390 to generate a second in-phase auxiliary signal 332. The first and second in-phase auxiliary signals 330, 332 may include signal components and jammer components. The in-phase auxiliary signals 330, 332 may be provided to the filter 312.

The second auxiliary mixer 308 may be configured to mix (e.g., perform a down-conversion operation) the first differential input signal 360 with a local oscillator signal 392 (e.g., a quadrature local oscillator signal (LO_{Q})) to generate a first quadrature auxiliary signal 334. The second auxiliary mixer 308 may also be configured to mix (e.g., perform a down-conversion operation) the second differential input signal 360 with the local oscillator signal 392 to generate a second quadrature auxiliary signal 336. The first and second quadrature auxiliary signals 334, 336 may include signal components and jammer components. The quadrature auxiliary signals 334, 336 may be provided to the filter 312.

The filter 312 may be configured to tune to a frequency of the jammer components (e.g., tune to the “jammer frequency”) and to reverse (e.g., shift) the phase of the jammer components such that jammer components “cancel each other out” (or destructively interfere with other jammer components) at the input of the auxiliary mixers 306, 308. For example, the filter 312 may be configured to generate a “low impedance” state for the jammer components at an input of the auxiliary path (e.g., the input of the auxiliary mixers 306, 308) by “canceling” jammer components at the input of the auxiliary mixers 306, 308.

Referring to FIG. 4, an exemplary embodiment of the filter 312 is shown. A first terminal of the filter 312 may be coupled to receive the first in-phase auxiliary signal (I+) 330, a second terminal of the filter 312 may be coupled to receive the first quadrature auxiliary signal (Q+) 334, a third terminal of the filter 312 may be coupled to receive the second in-phase auxiliary signal (I−) 332, and a fourth terminal of the filter 312 may be coupled to receive the second quadrature auxiliary signal (Q−) 336.

The first terminal of the filter 312 may be coupled to a first terminal of a capacitor 402 and to a first terminal of a resistor 404. The second terminal of the filter 312 may be coupled to a first terminal of a capacitor 412 and to a first terminal of a resistor 414. The third terminal of the filter 312 may be coupled to a first terminal of a capacitor 422 and to a first terminal of a resistor 424. The fourth terminal of the filter 312 may be coupled to a first terminal of a capacitor 432 and to a first terminal of a resistor 434.

A second terminal of the capacitor 402 may be selectively coupled to a second terminal of the resistor 434 via a switch 406, and a second terminal of the capacitor 412 may be selectively coupled to a second terminal of the resistor 404 via a switch 416. A second terminal of the capacitor 422 may be selectively coupled to a second terminal of the resistor 414 via a switch 426, and a second terminal of the capacitor 432 may be selectively coupled to a second terminal of the resistor 424 via a switch 436.

The second terminal of the capacitor 402 may further be selectively coupled to the second terminal of the resistor 414 via a switch 408, and the second terminal of the capacitor 412 may further be selectively coupled to the second terminal of the resistor 424 via a switch 418. The second terminal of the capacitor 422 may further be selectively coupled to the second terminal of the resistor 434 via a switch 428, and the second terminal of the capacitor 432 may further be selectively coupled to the second terminal of the resistor 404 via a switch 438.

The resistor and capacitor values may be selected to produce the jammer frequency at which the filter 312 substantially reduces down-converted jammer components in the auxiliary signals 330-336 provided to the filter 312. For example, during operation, the filter 312 may rotate the phase of the jammer components in the signals 330-336 to substantially attenuate the jammer components.

To illustrate, the capacitor 402 may be configured to have substantially the same impedance as the resistor 404 at the jammer frequency. Thus, at a first node (N₁), a first jammer current (Itx) from the first in-phase auxiliary signal (I+) 330 may be equally split between the path associated with the resistor 404 and the path associated with the capacitor 402. Upon passing the capacitor 402, the first jammer current (Itx) from the first in-phase auxiliary signal (I+) 330 may undergo a −90 degree phase shift and generate a resulting jammer current (−jtx). The “−j” signifies the −90 degree phase shift in the first jammer current (Itx) from the first in-phase auxiliary signal (I+) after passing through the capacitor 402. The lower frequency in-band signal components (e.g., a signal current) of the first in-phase auxiliary signal (I+) do not propagate through the capacitor 402 because of the capacitive coupling.

The capacitor 412 may be configured to have substantially the same impedance as the resistor 414 at the jammer frequency. Thus, at a second node (N₂), a second jammer current (jItx) from the first quadrature auxiliary signal (Q+) 334 may be equally split between the path associated with the resistor 414 and the path associated with the capacitor 412. Because the first quadrature auxiliary signal (Q+) 334 is approximately 90 degrees phase-shifted from the first in-phase auxiliary signal (I+) 330, the second jammer current (jItx) is approximately 90 degrees phase-shifted from the first jammer current (Itx) (e.g., “j” signifies a +90 degree phase shift). The resulting jammer current (−jItx) passing through the capacitor 402 and the second jammer current (jItx) passing through the resistor 414 may have substantially equal magnitudes with a phase difference of 180 degrees. The 180 degree phase difference may result in a cancellation between the resulting jammer current (−jItx) and the second jammer current (jItx), thereby cancelling jammer components when the switch 406 is open and the switch 408 is closed.

The capacitor 422 may be configured to have substantially the same impedance as the resistor 424 at the jammer frequency. Thus, at a third node (N₃), a third jammer current (−Itx) from the second in-phase auxiliary signal (I−) 332 may be equally split between the path associated with the resistor 424 and the path associated with the capacitor 422. Upon passing the capacitor 422, the third jammer current (−Itx) from the second in-phase auxiliary signal (I−) 332 may undergo a −90 degree phase shift and generate a resulting jammer current (jtx). The signal components (e.g., a signal current) of the second in-phase auxiliary signal (I−) do not propagate through the capacitor 422 because of the capacitive coupling.

The capacitor 432 may be configured to have substantially the same impedance as the resistor 434 at the jammer frequency. Thus, at a fourth node (N₄), a fourth jammer current (−jItx) from the second quadrature auxiliary signal (Q−) 336 may be equally split between the path associated with the resistor 434 and the path associated with the capacitor 432. Because the second quadrature auxiliary signal (Q−) 336 is approximately 90 degrees phase-shifted from the second in-phase auxiliary signal (I−) 332, the fourth jammer current (−jItx) is approximately 90 degrees phase-shifted from the third jammer current (−Itx). The resulting jammer current (jItx) passing through the capacitor 422 and the fourth jammer current (−jItx) passing through the resistor 434 may have substantially equal magnitudes with a phase difference of 180 degrees. The 180 degree phase difference results in a cancellation between the resulting jammer current (jItx) and the fourth jammer current (−jItx), thereby cancelling jammer components when the switch 426 is open and the switch 428 is closed.

Additionally, when the switch 416 is closed and the switch 418 is open, the first jammer current (Itx) from the first in-phase auxiliary signal (I+) 330 may be canceled with a resulting jammer current (−Itx) based on a phase shift of the first quadrature auxiliary signal (Q+) 334. For example, the second jammer current (jItx) from the first quadrature auxiliary signal (Q+) 334 may pass through the capacitor 412. Upon passing the capacitor 412, the second jammer current (jItx) may undergo a −90 degree phase shift and generate the resulting jammer current (−Itx). The 180 degree phase difference may result in a cancellation between the resulting jammer current (−Itx) and the first jammer current (Itx), thereby cancelling jammer components.

In a similar manner, when the switch 436 is closed and the switch 438 is open, the third jammer current (−Itx) from the second in-phase auxiliary signal (I−) 332 may be canceled with a resulting jammer current (Itx) based on a phase shift of the second quadrature auxiliary signal (Q−) 336. For example, the fourth jammer current (−jItx) from the second quadrature auxiliary signal (Q−) 336 may pass through the capacitor 432. Upon passing the capacitor 432, the fourth jammer current (−jItx) may undergo a −90 degree phase shift and generate the resulting jammer current (Itx). The 180 degree phase difference may result in a cancellation between the resulting jammer current (Itx) and the third jammer current (−Itx), thereby cancelling jammer components.

The filter 312 may be reconfigurable (e.g., a reconfigurable jammer filter). For example, the filter 312 may operate to attenuate high side jammer components and low side jammer components. For example, when switches 406, 418, 426, and 438 are closed, and switches 408, 416, 428, and 436 are open, the filter 312 may use capacitive phase shifting (as described above) to attenuate the jammer components.

By assuming the input signal has both high side jammer components and low side jammer components, the frequency for high side jammer is ω_{LO}+ω_{Tx}, the voltage swing is V_{LO+Tx}. The frequency for lower side jammer is ω_{LO}−ω_{Tx}, and the voltage swing is V_{LO-Tx}. The frequency voltage swings for the high side jammer and the low side jammer may be represented as:

V_{LO+Tx}(t)=V_{LO+Tx}×cos(ω_{LO+Tx}×t)

V_{LO-Tx}(t)=V_{LO-Tx}×cos(ω_{LO-Tx}×t)

Neglecting the very high frequency part, the jammer signals at the in-phase auxiliary mixer output and quadrature-phase may be represented as:

$${V}_{aux\_IF} ( t ) = \frac{{V}_{LO + Tx}}{2} \times sin ( {ω}_{Tx} + t ) + \frac{{V}_{Lo - Tx}}{2} \times sin ( {ω}_{Tx} + t )$$

$${V}_{{aux}_{I} \_QF} ( t ) = \frac{{V}_{LO + Tx}}{2} \times cos ( {ω}_{Tx} + t ) + \frac{{V}_{Lo - Tx}}{2} \times cos ( {ω}_{Tx} + t )$$

By applying 90 degree shift to in-phase auxiliary mixer output and combined with quadrature-phase mixer output, the signal at the notch filter output may be represented as:

$$\begin{matrix}{V}_{{aux}_{{Q}_{+}}} ( t ) = {V}_{{aux}_{I} \_QF} ( t ) + {V}_{{aux}_{I} \_IF} ( t ) \times j \\ = \frac{{V}_{LO - Tx}}{2} \times cos ( {ω}_{Tx} \times t ) \\ ( rejected LO + Tx Jammer \to High Side Rejection )\end{matrix}$$

Similar high side rejection can be obtained at the other notch filter output by applying a 90 degree phase shift to corresponding auxiliary mixer output. It is shown in FIG. 4 with switches 408, 418, 428 and 438 open, while switches 406,416,426 and 436 are closed.

Alternatively, by applying a −90 degree shift to an in-phase auxiliary mixer output combined with a quadrature mixer output, the signal at the combined output will be:

$$\begin{matrix}{V}_{{aux}_{{Q}_{+}}} ( t ) = {V}_{{aux}_{I} \_QF} ( t ) - {V}_{{aux}_{I} \_IF} ( t ) \times j \\ \frac{{V}_{LO + Tx}}{2} \times cos ( {ω}_{Tx} \times t ) \\ ( rejected LO - Tx Jammer \to Low Side Rejection )\end{matrix}$$

Similar high side rejection can be obtained at the other notch filter output by applying 90 degree phase shift to corresponding auxiliary mixer output. It is shown in FIG. 4 with switches 408,418,428 and 438 closed, while switches 406,416,426 and 436 open.

Although the filter 312 includes a resistive-capacitive configuration operable to rotate the phase of jammer component by approximately 90 degrees for jammer attenuation, in other embodiments, the filter 312 may include alternating current (AC) configurations to rotate the phase of jammer components by different magnitudes. As a non-liming example, the filter 312 may include AC configurations to rotate the phase of jammer components by 60 degrees for jammer configuration.

Referring back to FIG. 3, the operations of the filter 312 may used to reduce impedance at inputs of the first auxiliary mixer 306 and inputs of the second auxiliary mixer 308. For example, the auxiliary mixers 306, 308 may be passive mixers (e.g., dual-direction mixers) such that jammer current cancellation at the filter 312, as described with respect to FIG. 4, may be “up-converted” to the inputs of the auxiliary mixers 306, 308. Reducing the jammer current at the input of the auxiliary mixers 306, 308 may generate reduced impedance at the input of the auxiliary mixers 306, 308.

The reduced jammer components in the differential input signals 360, 362 provided to the first main mixer 304 and to the second main mixer 310 may be based on an impedance ratio between the main mixer 304, 310 inputs and the auxiliary mixer 306, 308 inputs. For example, at the jammer frequency, the impedance at the input of the auxiliary mixers 306, 308 may be relatively low compared to the impedance at the input of the main mixers 304, 310, causing the jammer components to propagate to the auxiliary mixers 306, 308. Thus, the main mixers 304, 310 may receive signal components (e.g., the “desired” reception signal) from the differential input signals 360, 362 and the jammer components may be effectively attenuated via the auxiliary path and the filter 312.

The first main mixer 304 and the second main mixer 310 may be included in a main mixing path. The first main mixer 304 may be an in-phase mixer, and the second main mixer 310 may be a quadrature mixer. The first main mixer 304 may be configured to mix (e.g., perform a down-conversion operation) the signal components of the first differential input signal 360 with the local oscillator signal 390 to generate a first in-phase signal 370 (e.g., a baseband signal having signal components). The first main mixer 304 may also be configured to mix the signal components of the second differential input signal 362 with the local oscillator signal 390 to generate a second in-phase signal 372 (e.g., a baseband signal having signal components). The in-phase signals 370, 372 may be provided to the first TIA 314.

The second main mixer 310 may be configured to mix the signal components of the first differential input signal 360 with the local oscillator signal 392 to generate a first quadrature signal 374 (e.g., a baseband signal having signal components). The second main mixer 310 may also be configured to mix the signal components of the second differential input signal 362 with the local oscillator signal 392 to generate a second quadrature signal 376 (e.g., a baseband signal having signal components). The quadrature signals 374, 376 may be provided to the second TIA 316.

The TIAs 314, 316 may operate as current to voltage converters and may be implemented using operational amplifiers. For example, the first TIA 314 may be configured to amplify the first in-phase signal 370 and to convert the amplified signal into a voltage signal. The first TIA 314 may also be configured to amplify the second in-phase signal 372 and to convert the amplified signal into a voltage signal. In a similar manner, the second TIA 316 may be configured to amplify the first quadrature signal 374 and to convert the amplified signal to a voltage signal. The second TIA 316 may also be configured to amplify the second quadrature signal 376 and to convert the amplified signal into a voltage signal. The amplified signals may be provided to additional receive circuitry (e.g., the receive circuits 242pk of FIG. 2) for additional signal processing.

The system of FIG. 3 may utilize auxiliary mixing paths to provide jammer cancellation. For example, the main mixing path (e.g., the main mixers 304, 310) and the auxiliary mixing path 370 (e.g., the auxiliary mixers 306, 308) may be separated such that the auxiliary mixing path 370 may perform jammer cancellation in conjunction with the filter 312. Using the auxiliary mixing path 370 may enable the filter 312 to include larger resistors (as compared to a notch filter in the main mixing path) and may enable capacitors to be locally placed within the filter 312 to improve I/Q matching with reduced impact (e.g., reduced filtering) on the signal components. The auxiliary mixing path 370 can be also controlled independently when the jammer is smaller or located further away, so that additional power consumption can be saved.

Using the auxiliary path for jammer cancellation may also reduce the distance between the main mixers 304, 310 and the TIAs 314, 316, respectively, because the need for a notch filter between the main mixers 304, 310 and the TIAs 314, 316 may be relaxed. Thus, using the auxiliary path for jammer cancellation may reduce die area consumption.

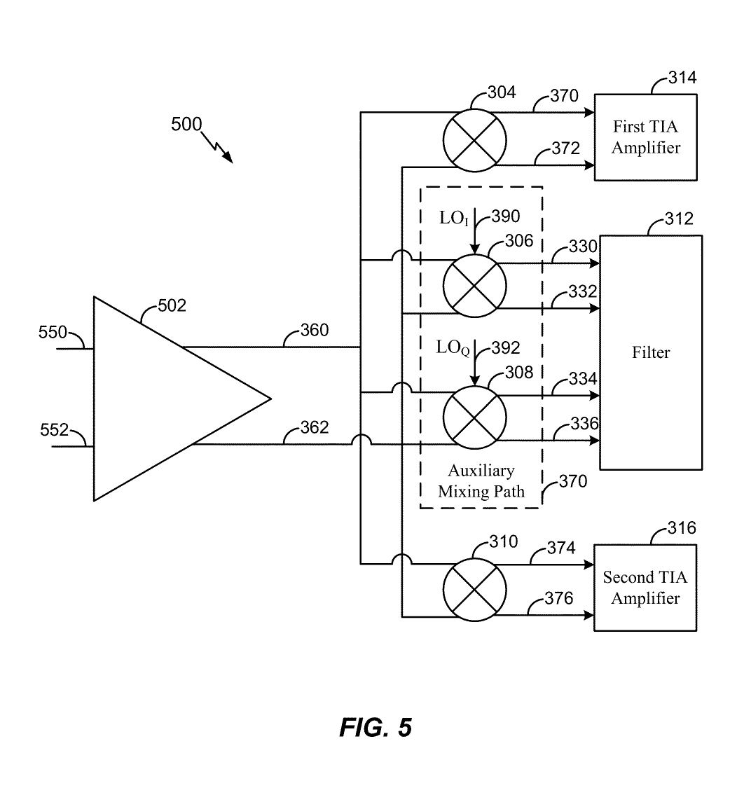

Referring to FIG. 5, another exemplary embodiment of a system 500 that is operable to reduce jammers is shown. The system 500 includes a low noise amplifier (LNA) 502, the first main mixer 304, the first auxiliary mixer 306, the second auxiliary mixer 308, the second main mixer 310, the filter 312, the first TIA 314, and the second TIA 316. In an exemplary embodiment, the LNA 502 may correspond to, or may be included in, the LNA 240pk of FIG. 2.

Differential input signals 550, 552 may be received at the LNA 502. The differential input signals 550, 552 may include signal components and jammer components. The LNA 502 may be configured to amplify the differential input signals 550, 552 to generate the first differential input signal 360 and the second differential input signal 362. For example, LNA 502 may be a differential LNA. The first main mixer 304, the first auxiliary mixer 306, the second auxiliary mixer 308, the second main mixer 310, the filter 312, the first TIA 314, and the second TIA 316 may operate in a substantially similar manner as described with respect to FIGS. 3-4.

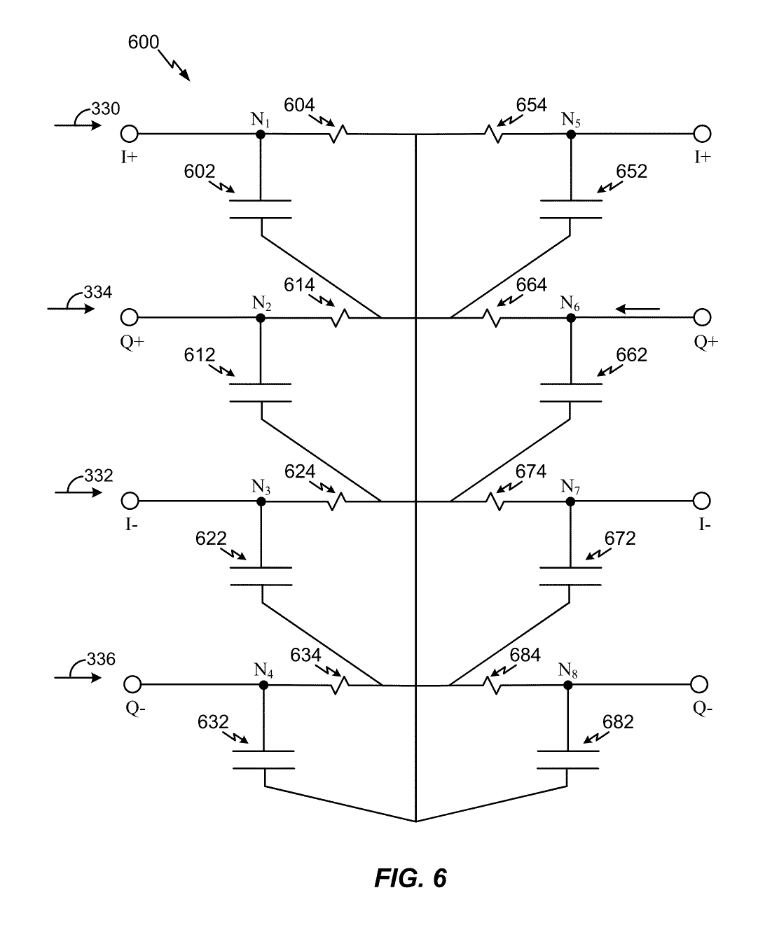

Referring to FIG. 6, another exemplary embodiment of a notch filter 600 is shown. In an exemplary embodiment, the notch filter 600 may correspond to the notch filter 212 of FIG. 2. In another exemplary embodiment, the notch filter 600 may be implemented with the system 300 of FIG. 3 or the system 500 of FIG. 5. For example, the notch filter 600 may replace the filter 312 of FIGS. 3 and 5. The notch filter 600 removes the switches in the notch filter 400, and behaves as the combination of high side jammer notcher and low side jammer notcher simultaneously. The difference between notch filter 600 and notch filter 400 is that notch filter 400 may operate either as a high side jammer notcher or as a low side jammer notcher at a given time, while notch filter 600 can notch high side jammer components and low side jammer components simultaneously.

A first terminal of the notch filter 600 may be coupled to receive the first in-phase auxiliary signal (I+) 330, a second terminal of the notch filter 600 may be coupled to receive the first quadrature auxiliary signal (Q+) 334, a third terminal of the notch filter 600 may be coupled to receive the second in-phase auxiliary signal (I−) 332, and a fourth terminal of the notch filter 600 may be coupled to receive the second quadrature auxiliary signal (Q−) 336.

The first terminal of the notch filter 600 may be coupled to a first terminal of a capacitor 602 and to a first terminal of a resistor 604. The second terminal of the notch filter 600 may be coupled to a first terminal of a capacitor 612 and to a first terminal of a resistor 614. The third terminal of the notch filter 600 may be coupled to a first terminal of a capacitor 622 and to a first terminal of a resistor 624. The fourth terminal of the notch filter 600 may be coupled to a first terminal of a capacitor 632 and to a first terminal of a resistor 634.

A second terminal of the capacitor 602 may be coupled to a second terminal of the resistor 614, and a second terminal of the capacitor 612 may be coupled to a second terminal of the resistor 624. A second terminal of the capacitor 622 may be coupled to a second terminal of the resistor 634. The capacitors 602, 612, 622, 632 and the resistors 604, 614, 624, 634 may function as a low side jammer canceller.

A first terminal of a resistor 654 may be coupled to a second terminal of the resistor 604, and a second terminal of the resistor 654 may be coupled to a first terminal of a capacitor 652. A first terminal of a resistor 664 may be coupled to the second terminal of the resistor 614 and to a second terminal of the capacitor 652, and a second terminal of the resistor 664 may be coupled to a first terminal of a capacitor 662. A first terminal of a resistor 674 may be coupled to the second terminal of the resistor 624 and to a second terminal of the capacitor 662, and a second terminal of the resistor 674 may be coupled to a first terminal of a capacitor 672. A first terminal of a resistor 684 may be coupled to the second terminal of the resistor 634 and to a second terminal of the capacitor 672, and a second terminal of the resistor 684 may be coupled to a first terminal of a capacitor 682. A second terminal of the capacitor 682 may be coupled to a second terminal of the capacitor 632. The capacitors 652, 662, 672, 682 and the resistors 654, 664, 674, 684 may function as a high side jammer canceller.

By combination of the capacitors 602, 612, 622, 632 and the resistors 604, 614, 624, 634, as well as the capacitors 652, 662, 672, 682 and the resistors 654, 664, 674, 684, both high side jammer and low side jammer are notched at the notch filter output.

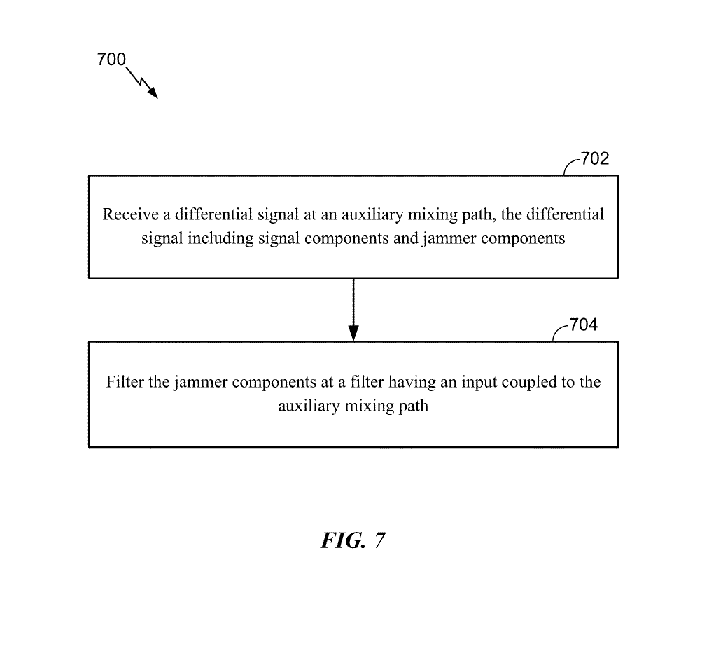

Referring to FIG. 7, a flowchart illustrates an exemplary embodiment of a method 500 for reducing jammers. In an exemplary embodiment, the method 700 may be performed using the wireless device 110 of FIGS. 1-2, the system 300 of FIG. 3, the filter 312 of FIGS. 3-5, the notch filter 600 of FIG. 6, or any combination thereof.

The method 700 includes receiving a differential signal at an auxiliary mixing path, the differential signal including signal components and jammer components, at 702. For example, referring to FIG. 3, the auxiliary mixing path 370 may receive the differential input signals 360, 362 from the transformer 303. Referring to FIG. 5, the auxiliary mixing path 370 may receive the differential input signals 360, 362 from LNA 502. The differential input signals 360, 362 may include signal components and jammer components. The differential input signals 360, 362 may be provided to the first auxiliary mixer 306 of the auxiliary mixing path 370 and to the second auxiliary mixer 308 of the auxiliary mixing path 370. The auxiliary mixers 306, 308 may mix (e.g., down-convert) the differential input signals 360, 362 to generate auxiliary signals 330-336. The auxiliary signals 330-336 may be provided to the filter 312.

The jammer components may be filtered at a filter having an input coupled to the auxiliary mixing path, at 704. For example, referring to FIG. 3, the filter 312 may be tuned to a frequency of the jammer components and may perform a phase-shift operation on the jammer components (as described with respect to FIG. 4) to attenuate the jammer components of the differential input signals 360, 362. The operations of the filter 312 may used to reduce impedance at inputs of the first auxiliary mixer 306 and inputs of the second auxiliary mixer 308. For example, the auxiliary mixers 306, 308 may be passive mixers (e.g., dual-direction mixers) such that jammer cancellation at the output of the auxiliary mixers 306, 308 (e.g., jammer current cancellation at the filter 312 as described with respect to FIG. 4) may be “up-converted” to the inputs of the auxiliary mixers 306, 308. Reducing the jammer current at the input of the auxiliary mixers 306, 308 may generate reduced impedance at the input of the auxiliary mixers 306, 308. For example, reducing the jammer current at the input of the auxiliary mixers 306, 308 may, in effect, function as providing a jammer cancellation signal to the differential input signals 360, 362.

The method 700 of FIG. 7 may utilize auxiliary mixing paths to achieve jammer cancellation. For example, the auxiliary mixing path 370 (e.g., the auxiliary mixers 306, 308) may be separated from the main mixers 304, 310 such that the auxiliary mixing path 370 may perform jammer cancellation in conjunction with the filter 312. Using the auxiliary mixing path 370 may enable the filter 312 to include larger resistors (as compared to a notch filter in the main mixing path) and may enable capacitors to be locally placed within the filter 312 to improve I/Q matching with reduced impact (e.g., reduced filtering) on the signal components

In conjunction with the described embodiments, an apparatus includes means for receiving a differential signal at an auxiliary mixing path. For example, the means for receiving the differential signal may include the first auxiliary mixer 206 of FIG. 2, the second auxiliary mixer 208 of FIG. 2, the auxiliary mixing path 370 of FIGS. 3 and 5, the first auxiliary mixer 306 of FIGS. 3 and 5, the second auxiliary mixer 308 of FIGS. 3 and 5, one or more other devices, circuits, or any combination thereof.

The apparatus may also include means for filtering having an input coupled to the first means for receiving the differential signal. For example, the means for filtering may include the filter 212 of FIG. 2, the filter 312 of FIGS. 3-5, the filter 600 of FIG. 6, one or more other devices, circuits, or any combination thereof.

The apparatus may also include first means for mixing configured to receive the differential signal. For example, the first means for mixing may include the first auxiliary mixer 206 of FIG. 2, the first auxiliary mixer 306 of FIGS. 3-5, one or more other devices, circuits, or any combination thereof.

The apparatus may also include second means for mixing configured to receive the differential signal. For example, the second means for mixing may include the second auxiliary mixer 208 of FIG. 2, the second auxiliary mixer 308 of FIGS. 3-5, one or more other devices, circuits, or any combination thereof.

The apparatus may also include third means for mixing configured to receive the differential signal. For example, the third means for mixing may include the first main mixer 204 of FIG. 2, the first main mixer 304 of FIGS. 3-5, one or more other devices, circuits, or any combination thereof.

The apparatus may also include fourth means for mixing configured to receive the differential signal. For example, the fourth means for mixing may include the second main mixer 210 of FIG. 2, the second main mixer 310 of FIGS. 3-5, one or more other devices, circuits, or any combination thereof.

The apparatus may also include first means for amplifying coupled to the third means for mixing. For example, the first means for amplifying may include the first TIA 214 of FIG. 2, the first TIA 314 of FIGS. 3-5, one or more other devices, circuits, or any combination thereof.

The apparatus may also include second means for amplifying coupled to the fourth means for mixing. For example, the second means for amplifying may include the second TIA 216 of FIG. 2, the second TIA 316 of FIGS. 3-5, one or more other devices, circuits, or any combination thereof.

Those of skill would further appreciate that the various illustrative logical blocks, configurations, modules, circuits, and algorithm steps described in connection with the embodiments disclosed herein may be implemented as electronic hardware, computer software executed by a processor, or combinations of both. Various illustrative components, blocks, configurations, modules, circuits, and steps have been described above generally in terms of their functionality. Whether such functionality is implemented as hardware or processor executable instructions depends upon the particular application and design constraints imposed on the overall system. Skilled artisans may implement the described functionality in varying ways for each particular application, but such implementation decisions should not be interpreted as causing a departure from the scope of the present disclosure.

The steps of a method or algorithm described in connection with the embodiments disclosed herein may be embodied directly in hardware, in a software module executed by a processor, or in a combination of the two. A software module may reside in random access memory (RAM), flash memory, read-only memory (ROM), programmable read-only memory (PROM), erasable programmable read-only memory (EPROM), electrically erasable programmable read-only memory (EEPROM), registers, hard disk, a removable disk, a compact disc read-only memory (CD-ROM), or any other form of non-transient storage medium known in the art. An exemplary storage medium is coupled to the processor such that the processor can read information from, and write information to, the storage medium. In the alternative, the storage medium may be integral to the processor. The processor and the storage medium may reside in an application-specific integrated circuit (ASIC). The ASIC may reside in a computing device or a user terminal. In the alternative, the processor and the storage medium may reside as discrete components in a computing device or user terminal.

The previous description of the disclosed embodiments is provided to enable a person skilled in the art to make or use the disclosed embodiments. Various modifications to these embodiments will be readily apparent to those skilled in the art, and the principles defined herein may be applied to other embodiments without departing from the scope of the disclosure. Thus, the present disclosure is not intended to be limited to the embodiments shown herein but is to be accorded the widest scope possible consistent with the principles and novel features as defined by the following claims.

What is claimed is:

1. An apparatus comprising:
an auxiliary mixing path configured to receive a differential signal; and
a filter having an input coupled to the auxiliary mixing path.

2. The apparatus of claim 1, wherein the auxiliary mixing path includes:
a first auxiliary mixer driven by an in-phase local oscillator (LO) signal, wherein the first auxiliary mixer is configured to receive the differential signal; and
a second auxiliary mixer driven by a quadrature LO signal, wherein the second auxiliary mixer is configured to receive the differential signal.

3. The apparatus of claim 2, wherein the first auxiliary mixer is an in-phase mixer, and wherein the second auxiliary mixer is a quadrature mixer.

4. The apparatus of claim 1, further comprising:
a main mixing path configured to receive the differential signal, wherein the main mixing path includes a first main mixer and a second main mixer.

5. The apparatus of claim 4, further comprising:
a first trans-impedance amplifier coupled to the first main mixer; and
a second trans-impedance amplifier coupled to the second main mixer.

6. The apparatus of claim 1, further comprising a low noise amplifier, wherein the auxiliary mixing path is coupled to an output of the low noise amplifier.

7. The apparatus of claim 6, wherein the low noise amplifier is a differential low noise amplifier that is configured to output the differential signal.

8. The apparatus of claim 1, further comprising:
a low noise amplifier; and
a transformer coupled to an output of the low noise amplifier, wherein the auxiliary mixing path is coupled to the transformer.

9. The apparatus of claim 1, wherein the filter is a notch filter that is tuned to a frequency of jammer components of the differential signal.

10. An apparatus comprising:
first means for receiving a differential signal at an auxiliary mixing path; and
means for filtering having an input coupled to the first means for receiving the differential signal.

11. The apparatus of claim 10, wherein the auxiliary mixing path includes:
first means for mixing configured to receive the differential signal, wherein the first means for mixing is driven by an in-phase local oscillator (LO) signal; and
second means for mixing configured to receive the differential signal, wherein the second means for mixing is driven by a quadrature LO signal.

12. The apparatus of claim 11, wherein the first means for mixing includes an in-phase mixer, and wherein the second means for mixing includes a quadrature mixer.

13. The apparatus of claim 10, further comprising:
second means for receiving the differential signal at a main mixing path, wherein the main mixing path includes third means for mixing and fourth means for mixing.

14. The apparatus of claim 13, further comprising:
first means for amplifying coupled to the third means for mixing; and
second means for amplifying coupled to the fourth means for mixing.

15. The apparatus of claim 10, further comprising means for generating the differential signal, wherein the first means for receiving the differential signal is coupled to an output of the means for generating the differential signal.

16. The apparatus of claim 15, wherein the means for generating the differential signal includes a low noise amplifier configured to output the differential signal.

17. The apparatus of claim 10, wherein the means for filtering includes a notch filter that is tuned to a frequency of jammer components of the differential signal.

18. A method comprising:
receiving a differential signal at an auxiliary mixing path; and
filtering the differential signal at a filter having an input coupled to the auxiliary mixing path.

19. The method of claim 18, further comprising generating the differential signal at a low noise amplifier.

20. The method of claim 18, wherein filtering the differential signal includes performing a phase-shift operation on jammer components of the differential signal.
